(19) United States
(12) Patent Application Publication
(10) Pub. No.: US 2025/0355806 A1
(43) Pub. Date: Nov. 20, 2025

(54) MEMORY DEVICE WITH FAILURE ADDRESS CACHE AND METHOD THEREOF

(71) Applicant: Winbond Electronics Corp., Taichung City (TW)

(72) Inventor: Yong Ju Kim, Zhubei City (TW)

(73) Assignee: Winbond Electronics Corp., Taichung City (TW)

(21) Appl. No.: 19/096,702

(22) Filed: Mar. 31, 2025

Related U.S. Application Data
(60) Provisional application No. 63/648,136, filed on May 15, 2024.

(51) Int. Cl. G06F 12/0802

(52) U.S. Cl. CPC G06F 12/0802

(57) ABSTRACT

A memory device includes a plurality of memory dies and a spare die that is stacked to the memory dies and is configured to repair a target memory die among the plurality of memory dies. Each of the spare die and the memory dies may include a failure address cache that records failure address information of the memory device. The failure address cache is configured receive an input address signal and output a hit signal or a miss signal, indicating a hit or a miss of the input address signal with failed addresses stored in the failure address cache. The memory device is configured to control an access to the memory dies and the spare die according to the hit signal or the miss signal.

### CROSS-REFERENCE TO RELATED APPLICATION

This application claims the priority benefit of U.S. provisional application Ser. No. 63/648,136, filed on May 15, 2024. The entirety of the above-mentioned patent application is hereby incorporated by reference herein and made a part of specification.

### BACKGROUND

### Technical Field

The disclosure generally relates to a semiconductor device, and more particularly relates to a stacked memory device with a repair scheme that may improve yield of the stacked memory device.

### Description of Related Art

A wafer-on-wafer stacking technique has been used to stack a logic wafer (i.e., system-on-chip wafer) and memory wafers together to form a stacked memory such as a dynamic random-access memory (DRAM). In the wafer-on-wafer stacking technique, good dies for stacking cannot be selected. As such, if there is a failed die in the stacked memory, the stacked memory should be repaired, to increase the yield of stacked memory.

It is desirable for a novel technique that may effectively repair the failed die in a memory device and may improve the yield the memory device fabrication.

### SUMMARY

A memory device includes a plurality of memory dies and a spare die that is stacked to the memory dies and is configured to repair a target memory die among the plurality of memory dies. Each of the spare die and the memory dies may include a failure address cache that records failure address information of the memory device. The failure address cache is configured to receive an input address signal and output a hit signal or a miss signal, indicating a hit or a miss of the input address signal with failed addresses stored in the failure address cache. The memory device is configured to control an access to the memory dies and the spare die according to the hit signal or the miss signal.

In accordance with embodiments of the disclosure, a method of operating a memory device that includes a plurality of memory dies and a spare die stacked to each other, each of the spare die and the memory dies comprises a failure address cache that records failure address information of the memory device is introduced. The method includes steps of receiving, by the failure address cache of the spare die or one of the memory dies, an input address signal; outputting, by the failure address cache of the spare die or the one of the memory dies, a hit signal or a miss signal indicating a hit or a miss of the input address signal with failed addresses stored in the failure address cache; and controlling an access to the memory dies and the spare die according to the hit signal or the miss signal.

A memory device includes a spare die and a plurality of memory dies, in which each of the spare die and the memory dies include a failure address cache that records failure address information of the memory device. When an input address signal is input to the failure address cache, the failure address cache may determine whether the input address signal hits or misses failed addresses stored in the failure address cache. When the failure address cache in the spare die hits, the failure address cache in the spare die allows an access to the memory array in the spare die. When the failure address cache in the spare die misses, the failure address cache in the spare die blocks the access to the memory array in the spare die. When the failure address cache in a memory die hits, the failure address cache in the memory die blocks the access to the memory array in the memory die. When the failure address cache in a memory die misses, the failure address cache in the memory die allows the access to the memory array in the memory die. In this way, failed bank groups, failed banks and/failed rows in the target memory die can be repaired efficiently using the failure address cache stored in each of the spare die and the memory dies.

To make the above features and advantages provided in one or more of the embodiments of the disclosure more comprehensible, several embodiments accompanied with drawings are described in detail as follows.

### BRIEF DESCRIPTION OF THE DRAWINGS

FIG. 1A and FIG. 1B illustrate a schematic diagram of a semiconductor stacked wafer for forming a memory device in accordance with some embodiments.

FIG. 2A and FIG. 2B illustrate schematic diagrams of failure address caches located in a failed die and a normal die in accordance with some embodiments.

FIG. 3A and FIG. 3B illustrate failure address caches that record failed bank group addresses and failed bank addresses in accordance with some embodiments.

FIG. 4A illustrates a process to determine a hit or a miss of an input bank group address signal or an input bank address signal using a failure address cache in accordance with some embodiments.

FIG. 4B and FIG. 4C illustrate processes for controlling accesses to a memory device based on a hit signal or a miss signal in accordance with some embodiments.

FIG. 5A illustrate a failure address cache that records failed row addresses in accordance with some embodiments.

FIG. 5B illustrates modulars of a failed row address field of a failure address cache in accordance with some embodiments.

FIG. 5C illustrates a process for generating a hit signal or a miss signal upon a receipt of an input row address signal in accordance with some embodiments.

FIG. 6A and FIG. 6B illustrate failure address caches that records failed row addresses in accordance with some embodiments.

FIG. 7A and FIG. 7B illustrate processes for generating a hit signal or a miss signal in accordance with some embodiments.

FIG. 8 illustrates a flowchart diagram of a method for operating a memory device in accordance with some embodiments.

### DESCRIPTION OF THE EMBODIMENTS

References are made in detail to the present preferred embodiments of the invention, examples of which are illustrated in the accompanying drawings. Wherever possible, the same reference numbers are used in the drawings and the description to refer to the same or like parts.

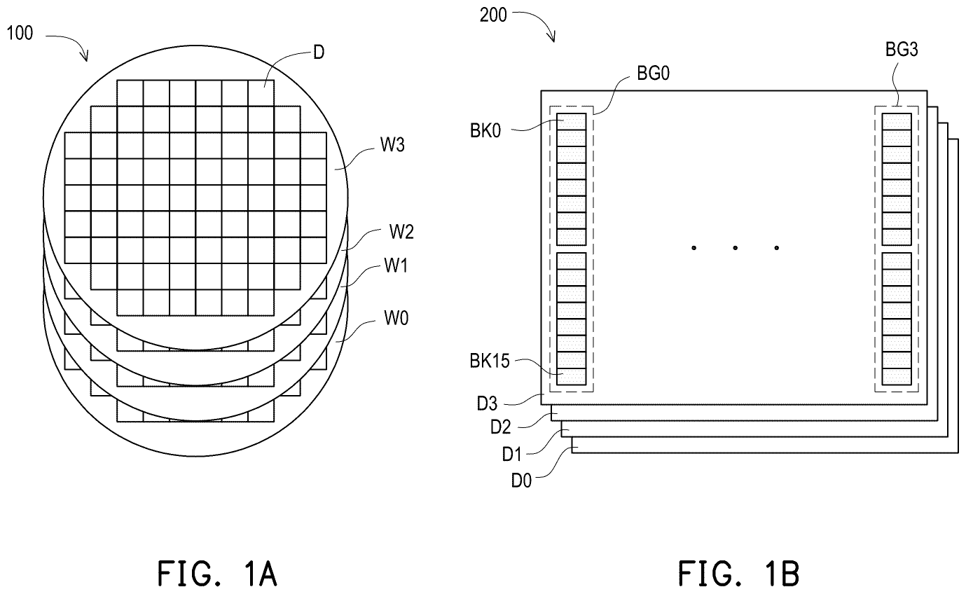

FIG. 1A and FIG. 1B illustrate a schematic diagram of a semiconductor stacked wafer 100 in accordance with some embodiments. The semiconductor stacked wafer 100 may include a plurality of wafers W0, W1, W2 and W3 which are stacked to each other. The wafers W0 to W3 of the semiconductor stacked wafer 100 may be stacked to each other using a wafer-on-wafer stacking technique. Each of the wafers W0 to W3 may include a plurality of dies D, and the dies in the wafers W0 to W3 may be stacked to each other to form a memory device. The memory device is a dynamic random-access memory (DRAM), but the disclosure is not limited to thereto. The disclosure does not intend to limit the type of the memory device, the number of the wafers W0 to W3 in the semiconductor stacked wafer 100 and the number of dies D per wafer.

The wafers W0 to W4 of the semiconductor stack wafer 100 may include a logic wafer, a spare wafer, and a plurality of memory wafers. The spare wafer of the semiconductor stack wafer 100 may be determined by programing a fuse. For simplicity, the wafer W0 of the semiconductor stacked wafer 100 is referred to as the logic wafer, the wafer W1 is referred to as the spare wafer, and the wafer W2 to W3 are referred to as memory wafers.

Please note that the disclosure does not intend to limit the number of the logic wafer, the number of the spare wafer and the number of the memory wafers in the semiconductor stacked wafer 100. Also, a position and arrangement of the logic wafer, the spare wafer and the memory wafers in the semiconductor stacked wafer 100 may vary depending on the design requirements.

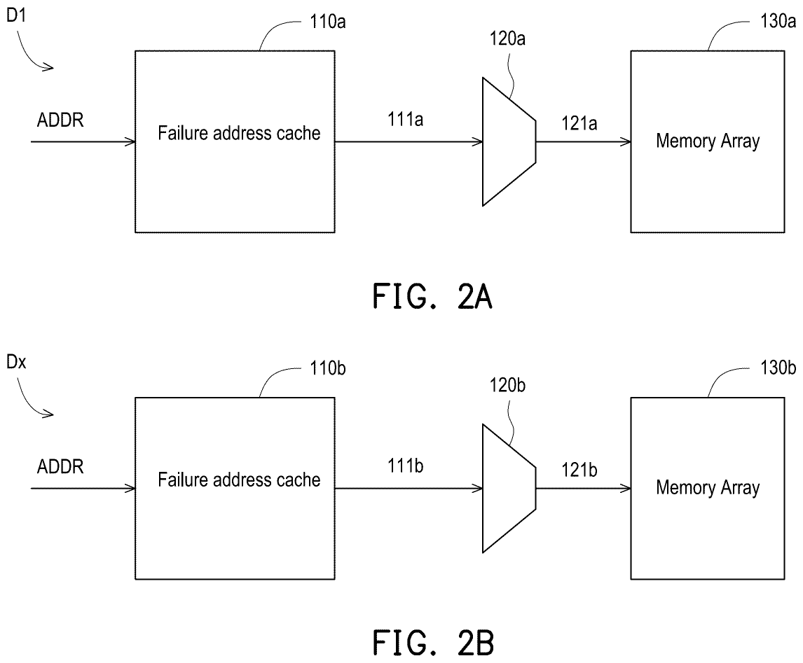

FIG. 2A to FIG. 2B illustrate schematic diagrams of a memory device 200 including plurality of dies D0, D1, D2 and D3 stacked to each other in accordance with some embodiments. The dies D0 to D3 are dies of the wafers W0 to W3, respectively. As such, the memory device 200 is formed by stacking a logic die D0 of the logic wafer W0, a spare die D1 of the spare wafer W1 and memory dies D2 and D3 of the memory wafer W2 and W3. It is appreciated that the spare wafer W1 may be determined after the memory device 200 is packaged by programming a fuse (not shown). The memory device 200 may include memory ranks (not show), each corresponds a number of dies among the dies D0 to D3. Each of the dies D0 to D3 may include a plurality of bank groups BG0 to BG3, and each of the bank groups BG0 to BG3 may include a plurality of memory banks BK0 to BK15. Each of the memory banks BK0 to BK15 may include a plurality of memory rows (not shown). In some embodiments, each of the dies D0 to D3 of the memory device 200 may include a failure address cache that record failed address information (i.e., failed memory ranks, failed memory bank groups, failed memory banks, failed memory rows) and/or pieces of information about repair information (i.e., replaced memory ranks, replaced memory bank groups, replaced memory banks, replaced memory rows).

FIG. 2A illustrates a schematic diagram of a failure address cache 110a located in a spare die (i.e., spare die D1 of the spare wafer W1 in FIG. 1) in accordance with some embodiments. As shown in FIG. 2A, the die D1 may include the failure address cache 110a, an access control block 120a and a memory array 130a. The failure address cache 110a may receive an input address signal ADDR, determine whether the input address signal ADDR hits one of the failed addresses recorded in the failure address cache 110a, and output a hit signal or a miss signal according to the determination. The input address signal ADDR may be an address of a bank group, an address of a bank or an address of a row. The hit signal is output when the input address signal ADDR hits a failed address recorded in the failure address cache 110a, and the miss signal is output when the input address signal ADDR missed all failed addresses recorded in the failure address cache 110a. The hit signal and the bit signal may be collectively referred to as a hit-miss signal 111a that is output by the failure address cache 110a.

The access control block 120a may receive the hit-miss signal 111a from the failure address cache 110a and is configured to transmit or block the input address signal ADDR and/or a command associated with the input address signal ADDR to the memory array 130a. The command may be a read command or a write command for performing a read operation or a write operation to the input address signal ADDR. In some embodiments, when the hit-miss signal 111a is the hit signal, the access control block 120a is configured to transmit the input address signal ADDR and/or the command to the memory array 130a. In other words, it allows an access the memory array 130a when the hit signal is output by the failure address cache 110a of the spare die D1. When the hit-miss signal 111a is the miss signal, the access control block 120a is configured to block a transmission of the input address signal ADDR and/or the command to the memory array 130a. In other words, it blocks the access to the memory array 130a when the miss signal is output by the failure address cache 110a of the spare die D1.

FIG. 2B illustrates a schematic diagram of a failure address cache 110b located at a normal die Dx (i.e., memory die D2 or D3 of the memory wafer W2 and W3 in FIG. 1) in accordance with some embodiments. As shown in FIG. 2B, the normal die Dx may include the failure address cache 110b, an access control block 120b and a memory array 130b. The failure address cache 110b may receive an input address signal ADDR, determine whether the input address signal ADDR hits one of the failed addresses recorded in the failure address cache 110b, and output a hit signal or a miss signal according to the determination. The information stored in the failure address cache 110b in FIG. 2B is same as the information stored in the failure address cache 110a shown in FIG. 2A. The hit signal is output when the input address signal ADDR hits a failed address recorded in the failure address cache 110b, and the miss signal is output when the input address signal ADDR missed all failed addresses recorded in the failure address cache 110b. The hit signal and the bit signal may be collectively referred to as a hit-miss signal 111b that is output by the failure address cache 110b.

The access control block 120b may receive the hit-miss signal 111b from the failure address cache 110b and is configured to transmit or block the input address signal ADDR and/or a command associated with the input address signal ADDR to the memory array 130b. When the hit-miss signal 111b is the hit signal, the access control block 120b is configured to block a transmission of the input address signal ADDR and/or the command to the memory array 130b. In other words, it blocks the access the memory array 130b when the hit signal is output by the failure address cache 110b of the normal die Dx. When the hit-miss signal 111b is the miss signal, the access control block 120b is configured to transmit the input address signal ADDR and/or the command to the memory array 130b. In other words, it allows the access to the memory array 130b when the miss signal is output by the failure address cache 110b of the normal die Dx. The functionalities of the access control blocks 120a and 120b in FIG. 2A and FIG. 2B may be implemented in the failure address caches 110a and 110b respectively.

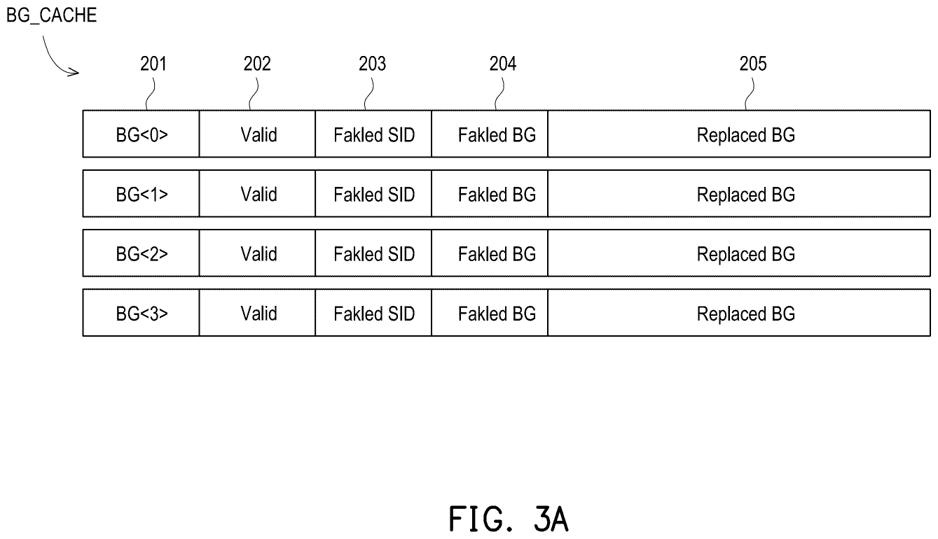

FIG. 3A illustrates a failure address cache BG_CACHE that records failed bank group addresses in accordance with some embodiments. The failure address cache BG_CACHE may be stored in each die (including both spare die and the memory dies) of the memory device 200. The failure address cache BG_CACHE may record information of failed bank groups of the memory device 200.

The failure address cache BG_CACHE may include a bank group field 201, a validity field 202, a failed rank identification field 203, a failed bank group address field 204 and a replaced bank group address field 205. The bank group field 201 may record information of failed bank groups in the dies of the memory device 200. The validity field 202 may record a validity status of each of the failed bank groups. The failed rank identification (ID) field 203 may record the rank ID of the memory rank that includes the failed bank group. The failed bank group address field 204 may record addresses of the failed bank groups in the memory device 200. The replaced bank group address field 205 may record address of the replaced bank group that is used to replace the failed bank groups. The replaced bank groups refer to the bank groups of the spare die D1 of the spare wafer W1 being used to replace the failed bank groups in one of the memory dies (i.e., the memory die D2 or D3 of the memory wafer W2 or W3). The input address signal is an input bank group address signal, and the failure address cache BG_CACHE may determine a hit or a miss of the input bank group address signal with failed bank group addresses stored in the failure address cache BG_CACHE.

FIG. 3B illustrates a failure address cache BK_CACHE that records failed bank addresses in accordance with some embodiments. The failure address cache BK_CACHE may be stored in each die (including both spare die and the memory dies) of the memory device 200. The failure address cache BK_CACHE may record information related to failed banks of the memory device 200.

The failure address cache BK_CACHE may include a failed rank identification field 301, a failed bank address field 202, a replaced bank address field 203 and a validity field 204. The failed rank identification (ID) field 301 may record the rank ID of the memory rank that includes the failed bank. The failed bank address field 302 may record addresses of the failed banks in the memory device 200. The replaced bank address field 203 may record addresses of the replaced banks that are used to replace the failed banks in the memory device 200. The replaced banks refer to the banks of the spare die D1 being used to replace the failed banks in one of the memory dies (i.e., the memory die D2 or D3 of the memory wafer W2 or W3). The validity field 304 may record a validity status of each of the failed banks in the failure address cache BK_CACHE.

When the input address signal is an input bank group address signal, the failure address cache BG_CACHE in FIG. 3A may be used to determine a hit or a miss of the input bank group address signal. When the input address signal is an input bank address signal, the failure address cache BK_CACHE in FIG. 3B may be used to determine a hit or a miss of the input bank address signal.

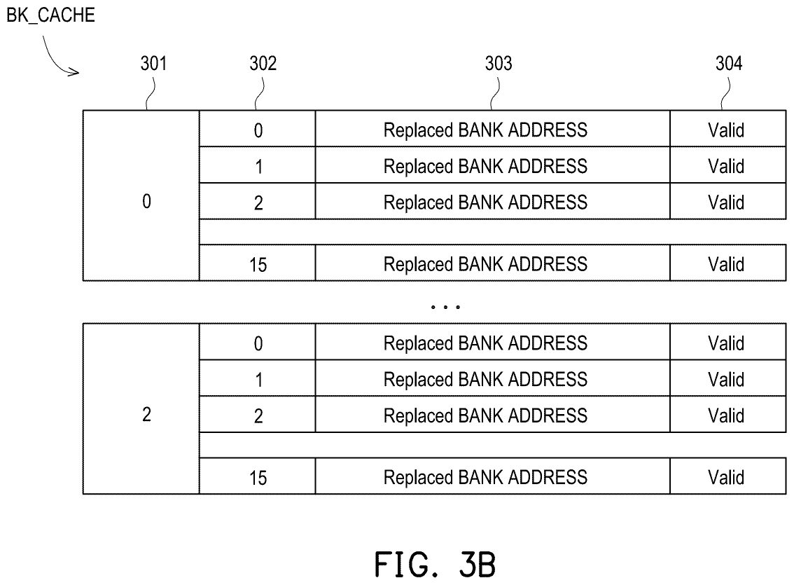

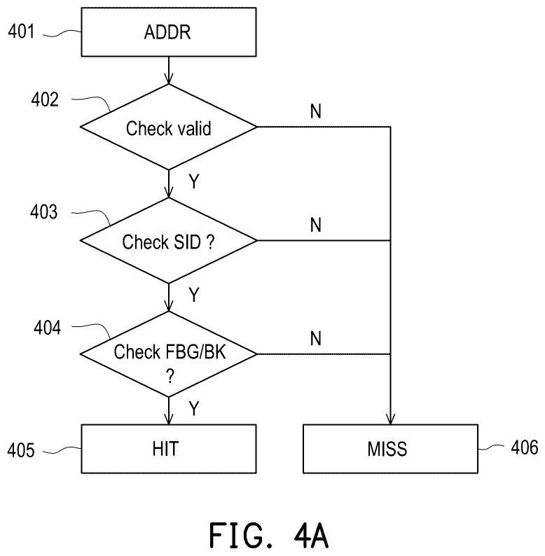

FIG. 4A illustrates a process to determine a hit or a miss of an input bank group address signal or an input bank address using a failure address cache in accordance with some embodiments. In block 401, the input address signal ADDR is input to the failure address cache stored in each die of the memory device 200. The input address signal ADDR may be the input bank group address signal which may identify a bank group of the memory device 200. In some alternative embodiments, the input address signal ADDR may be the input bank address signal which may identify a bank of the memory device 200.

In block 402, the failure address cache (i.e., failure address cache BG_CACHE or BK_CACHE) is configured to check validity statuses of the failed bank groups or the failed banks recorded in the failure address cache. In block 403, the failure address cache is configured to check whether the rank ID associated with the input address signal ADDR matches a failed rank ID recorded in the failure address cache. In block 404, the failure address cache is configured to check whether the input address signal ADDR matches a failed bank group address or a failed bank address recorded in the failure address cache.

The input address signal ADDR is the input bank group address signal that may identify a bank group of the memory device 200. Accordingly, the failure address cache BG_CACHE shown in FIG. 3A may output the hit signal or the miss signal upon a receipt of the input bank group address signal. The failure address cache BG_CACHE may determine whether the input bank group address signal matches one of the failed bank group addresses recorded in the failure address cache BG_CACHE (block 404). Meanwhile, the failure address cache BG_CACHE may determine whether the validity status in the address cache BG_CACHE is valid (block 402), and determine whether the rank ID associated with the input bank group address signal matches the failed rank ID recorded in the address cache BG_CACHE (block 403). In response to determining that the input bank group address signal matches a failed bank group address in the failure address cache BG_CACHE, the validity status of the failed bank group address in the failure address cache BG_CACHE is valid, and the rank ID associated with the input bank group address signal matches the rank ID of the failed bank group in failure address cache BG_CACHE, the failure address cache BG_CACHE outputs the hit signal (block 405). In response to determining that the input bank group address signal does not match any one of the failed bank group addresses in the failure address cache BG_CACHE, the validity status of the failed bank group address in the failure address cache BG_CACHE is invalid, and/or the rank ID associated with the input bank group address signal does not match the rank ID of the failed bank group in failure address cache BG_CACHE, the failure address cache BG_CACHE outputs the miss signal (block 406).

The input address signal ADDR is the input bank address signal that may identify a bank of the memory device 200. Accordingly, the failure address cache BK_CACHE shown in FIG. 3B may output the hit signal or the miss signal upon a receipt of the input bank address. The failure address cache BK_CACHE may determine whether the input bank address signal matches one of the failed bank addresses recorded in the failure address cache BK_CACHE (block 404). Meanwhile, the failure address cache BK_CACHE may determine whether the validity status in the address cache BK_CACHE is valid (block 402), and determine whether the rank ID associated with the input bank address signal matches the failed rank ID recorded in the address cache BK_CACHE (block 403). In response to determining that the input bank address signal matches a failed bank address in the failure address cache BK_CACHE, the validity status of the failed bank address in the failure address cache BK_CACHE is valid, and the rank ID associated with the input bank address signal matches the rank ID of the failed bank in failure address cache BK_CACHE, the failure address cache BK_CACHE outputs the hit signal (block 405). In response to determining that the input bank address signal does not match any one of the failed bank addresses in the failure address cache BK_CACHE, the validity status of the failed bank address in the failure address cache BK_CACHE is invalid, and/or the rank ID associated with the input bank address signal does not match the rank ID of the failed bank in failure address cache BK_CACHE, the failure address cache BK_CACHE outputs the miss signal (block 406).

FIG. 4B illustrates a process for controlling accesses to a memory device based on a hit signal in accordance with some embodiments. In block 405, the hit signal is output by the failure address cache (i.e., the failure address cache BG_CACHE in FIG. 3A or the failure address cache BK_CACHE in FIG. 3B). In block 407b, the failure address cache determines whether the failure address cache is located in the spare die (i.e., spare die D1 in wafer D1) or in a normal die (i.e., normal die D2 or D3 in wafer D2 or D3). When it determines that the failure address cache is located in the spare die D1, the failure address cache allows the access to the memory array by transmitting the replaced bank group address or the replaced bank address to the memory array (block 408b). In the block 408b, the failure address cache may further transmit a command (i.e., read command or a write command) associated with the input address signal ADDR to the memory array. When it determines that the failure address cache is located in the normal die of the wafers W2 or W3, the failure address cache may block the access to the memory array by blocking the transmission of the input bank group address signal or the input bank address and their associated command to the memory array (block 409b). In other words, the failure address cache in the spare die allows the access to the memory array when the failure address cache in the spare die is hit, and the failure address cache in the normal die blocks the access to the memory array when the failure address cache in the normal die is hit.

FIG. 4C illustrates a process for controlling accesses to a memory device based on a miss signal in accordance with some embodiments. In block 406, the miss signal is output by the failure address cache (i.e., the failure address cache BG_CACHE in FIG. 3A or the failure address cache BK_CACHE in FIG. 3B). In block 407c, the failure address cache determines whether the failure address cache is located in the spare die (i.e., spare die D1 in wafer D1) or in a normal die (i.e., normal die D2 or D3 in wafer D2 or D3). When it determines that the failure address cache is located in the spare die D1, the failure address cache blocks the access to the memory array by blocking the transmission of the replaced bank group address or the replaced bank address and their associated command to the memory array (block 408c). When it determines that the failure address cache is located in the normal die in the wafers W2 or W3, the failure address cache allows the access to the memory array by transmitting the input bank group address signal or the input bank address to the memory array (block 409c). In the block 409c, the failure address cache may further transmit the command associated with the input bank group address signal or the input bank address to the memory array (block 409c). In other words, the failure address cache in the spare die blocks the access to the memory array when the failure address cache in the spare die is missed, and the failure address cache in the normal die allows the access to the memory array when the failure address cache in the normal die is missed.

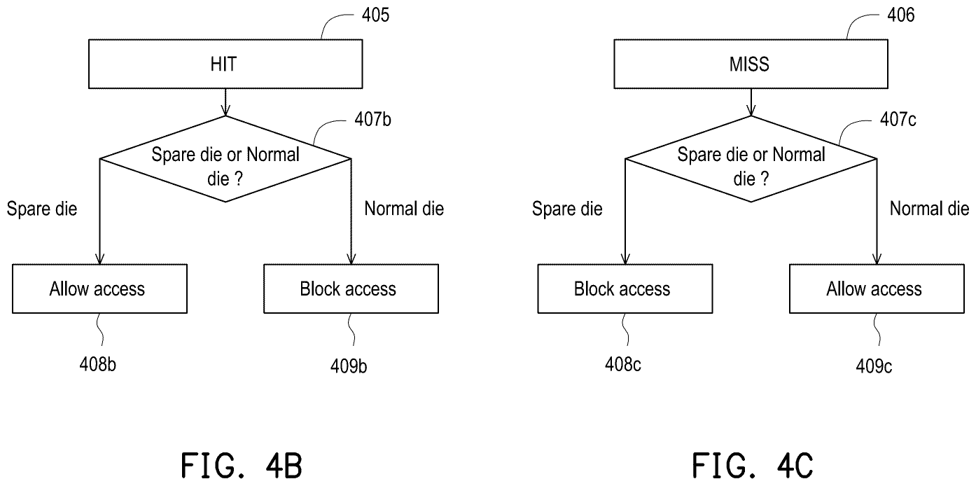

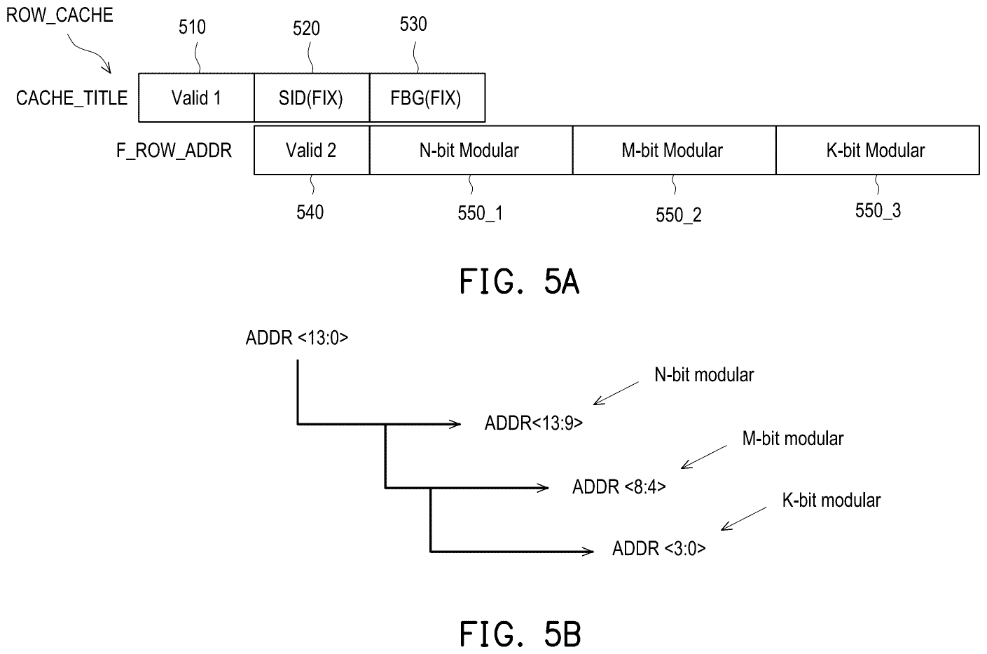

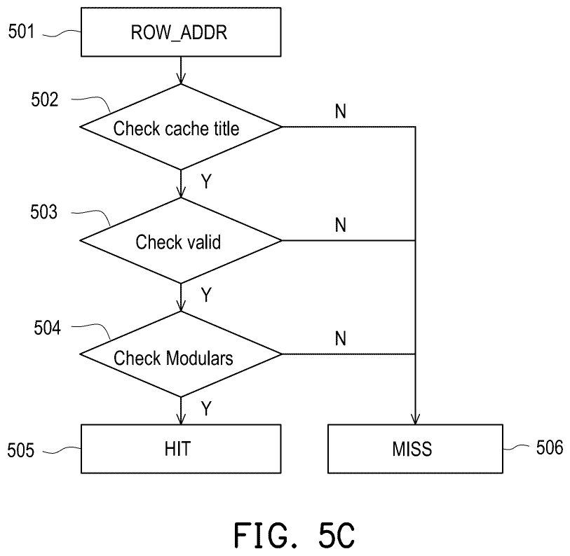

FIG. 5A illustrate a failure address cache ROW_CACHE that records failed row addresses in accordance with some embodiments. The failure address cache ROW_CACHE may record address information of failed rows in the memory device (i.e., memory device 200 in FIG. 1B) in accordance with some embodiments. The failure address cache ROW_CACHE may be stored in each die of the memory device 200.

As shown in FIG. 5A, the failure address cache ROW_CACHE may include a cache title field CACHE_TITLE and a failed row address field F_ROW_ADDR. The cache title field CACHE_TITLE is configured to record information of a cache title of the failure address cache ROW_CACHE. The cache title field CACHE_TITLE may include a first validity field 501, a rank ID field 502 and a failed bank group field 503. The first validity field 510 may record a validity status of the cache title, the rank ID field 520 may record identification information of rank that includes the failed row, and the failed bank group field 530 may record an address of a failed bank block that includes the failed row.

The failed row address field F_ROW_ADDR may include a second validity field 540 and a plurality of multi-bit modulars. The second validity field 540 may record the validity status of the failed row address field F_ROW_ADDR, and the multi-bit modulars may record a row address of a failed row of the memory device 200. As shown in FIG. 5A, the failed row address field F_ROW_ADDR may include a N-bit modular 550_1, a M-bit modular 550_2 and a K_bit modular 550_3. The N-bit modular 550_1, the M-bit modular 550_2 and the K_bit modular 550_3 are configured to record the row address of the failed row in the memory device 200.

FIG. 5B illustrates an example storing a row address of a failed row in the N-bit modular 550_1, the M-bit modular 550_2 and the K_bit modular 550_3 in accordance with some embodiments. As shown in FIG. 5B, the row address of a failed row may be represented by ADDR<13:0>, in which the data bits ADDR<13:9> are broken down to the N-bit modular, the data bits ADDR<8:4> are represented as the M-bit modular, and the data bits ADDR<3:0> are represented as the K-bit modular. It is appreciated that the disclosure does not intend to limit the bit number of the row address, the number of the modulars in the failed row address field F_ROW_ADDR of the failure address cache ROW_CACHE.

FIG. 5C illustrates a process for generating a hit signal or a miss signal upon a receipt of an input row address signal using a failure address cache ROW_CACHE in accordance with some embodiments. In block 501, the input row address ROW_ADDR is input to the failure address cache ROW_CACHE. In block 502, the failure address cache ROW_CACHE may check whether a cache title associated with the input row address ROW_ADDR matches a cache title stored in the failure address cache ROW_CACHE. In block 503, the failure address cache ROW_CACHE may check whether the validity status of validity fields in the failure address cache ROW_CACHE is valid. The failure address cache ROW_CACHE may check whether the validity statuses stored in the first validity field 501 and the second validity field 504 are valid or invalid. In block 504, the failure address cache ROW_CACHE may check whether multi-bit modulars associated with the input row address ROW_ADDR matches the multi-bit modulars stored in the failed row address field F_ROW_ADDR of the failure address cache ROW_CACHE.

In response to determine that the multi-bit modulars associated with the input row address ROW_ADDR matches multi-bit modulars stored in a failed row address field F_ROW_ADDR of the failure address cache ROW_CACHE (block 504), the cache title associated with the input row address ROW_ADDR matches the cache title of the failure address cache ROW_CACHE (block 502), and the validity statuses in the first validity field 501 and the second validity field 504 are valid (block 503), the failure address cache ROW_CACHE outputs the hit signal indicating that the input row address ROW_ADDR hits one of the failed rows stored in the failure address cache ROW_CACHE.

In response to determine that the multi-bit modulars associated with the input row address ROW_ADDR does not match multi-bit modulars stored in a failed row address field F_ROW_ADDR of the failure address cache ROW_CACHE (block 504), the cache title associated with the input row address ROW_ADDR does not match the cache title of the failure address cache ROW_CACHE (block 502), or the validity statuses in the first validity field 501 and the second validity field 504 are invalid (block 503), the failure address cache ROW_CACHE outputs the miss signal indicating that the input row address ROW_ADDR misses all the failed rows stored in the failure address cache ROW_CACHE.

The failure address cache ROW_CACHE may allow or block accesses to the memory according to the hit signal or the miss signal and the memory die that stores the failure address cache ROW_CACHE. For example, failure address cache ROW_CACHE in the spare die may allow the access to the memory upon the hit signal, and block the access to the memory upon the miss signal. The failure address cache ROW_CACHE in the normal die may block the access to the memory upon the hit signal, and allow the access to the memory upon the miss signal. The process of controlling the access the memory upon the hit or miss signal of the failure address cache ROW_CACHE may be same as the processes shown in FIG. 4B and FIG. 4C in some embodiments.

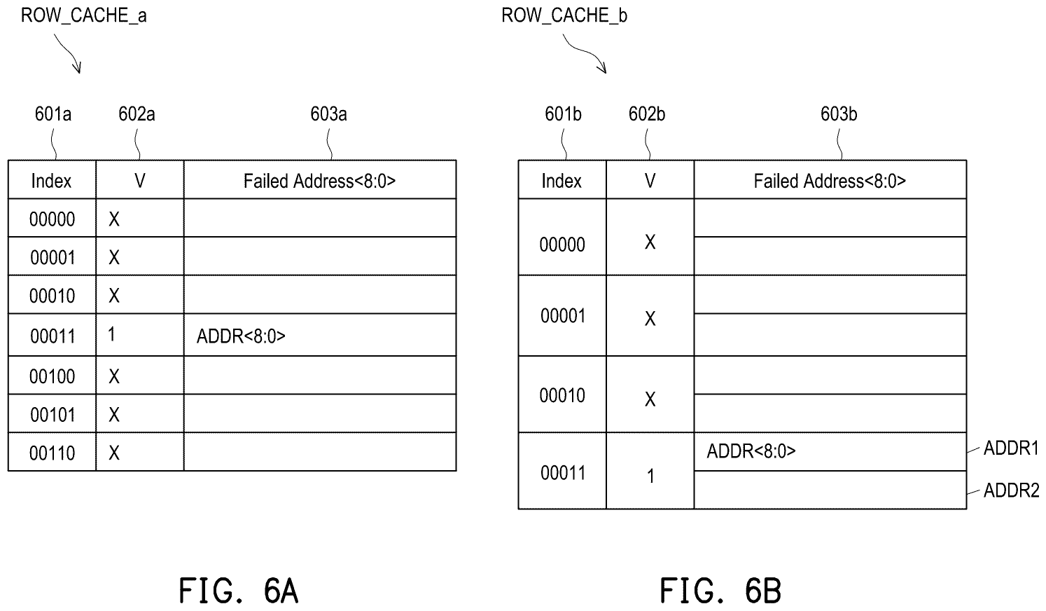

FIG. 6A illustrates a failure address cache ROW_CACHE_a that records failed row addresses in accordance with some embodiments. The failure address cache ROW_CACHE_a may record address information of failed rows in the memory device 200. The failure address cache ROW_CACHE_a may be stored in each die of the memory device 200.

As shown in FIG. 6A, the failure address cache ROW_CACHE_a may include an index field 601a, a validity field 602a and a failed row address field 603a. The index field 601a may record an index value for each row of the failure address cache ROW_CACHE_a, the validity field 602a may record a validity status of each row of the failure address cache ROW_CACHE_a, and the failed row address field 603a may record a failed row address of a failed row of the memory device (i.e., memory device 200 in FIG. 1B) in each row of the failure address cache ROW_CACHE_a. The index value stored in the index field 601a may be a 5-bit value, the validity status may be a 1-bit value, and the failed row address stored in the address field 603a may be a 9-bit value. It is appreciated that the disclosure does not intend to limit the bit number of values stored in each of the index field 601a, the validity field 602a and the failed row address field 603a of the failure address cache ROW_CACHE_a. As shown in FIG. 6A, each index value in the index field 601a may correspond to one failed row address in the failed row address field 603a (i.e., 1-1 mapping).

FIG. 6B illustrates a failure address cache ROW_CACHE_b that records failed row addresses in accordance with some alternative embodiments. The failure address cache ROW_CACHE_b may record address information of failed rows in the memory device 200. The failure address cache ROW_CACHE_b may be stored in each die of the memory device 200.

As shown in FIG. 6B, the failure address cache ROW_CACHE_b may include an index field 601b, a validity field 602b and a failed row address field 603b. The index field 601b and the validity field 602b of the failure address cache ROW_CACHE_b in FIG. 6B may be the same as the index field 601a and the validity field 602a of the failure address cache ROW_CACHE_a in FIG. 6A, thus the detailed description of the index field 601b and the validity field 602b are omitted hereafter. A difference between the failure address cache ROW_CACHE_b in FIG. 6B and the failure address cache ROW_CACHE_a in FIG. 6A is that each index of the failure address cache ROW_CACHE_b may correspond to multiple (i.e., two) failed row addresses ADDR1 and ADDR2. In other words, each index value in the index field 601b may correspond to multiple failed row addresses in the failed row address field 603b (i.e., 1-n mapping).

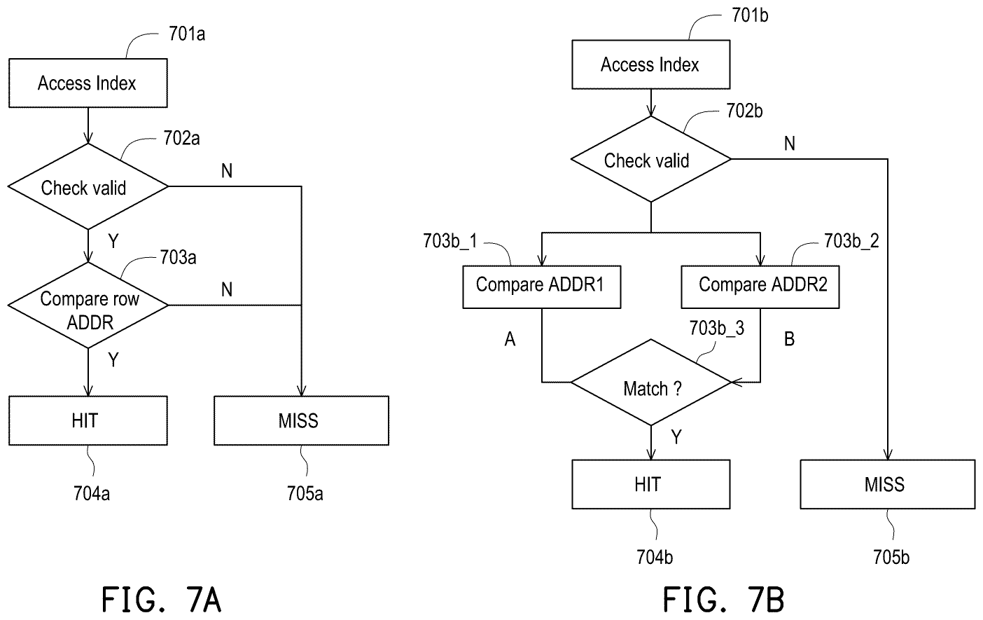

FIG. 7A illustrates a process for the failure address cache ROW_CACHE_a to output a hit signal or a miss signal upon an input row address signal in accordance with some embodiments. The input row address signal (not shown) may include to an input access index and an input row address.

In block 701a, the input access index is input to the failure address cache ROW_CACHE_a. In block 702a, the failure address cache ROW_CACHE_a may check the validity status corresponding to the input access index; and in block 702a, the failure address cache ROW_CACHE_a may compare the input row address with the failed row address stored in the failure address cache ROW_CACHE_a.

In response to determining that validity status corresponding to the input access index is valid (block 702a) and the input row address matches the failed row address corresponding to the input access index in the failure address cache ROW_CACHE_a (block 703a), the failure address cache ROW_CACHE_a outputs the hit signal (block 703a). In response to determining that validity status corresponding to the input access index is invalid (block 702a) and/or the input row address does not match the failed row address corresponding to the input access index in the failure address cache ROW_CACHE_a (block 704a), the failure address cache ROW_CACHE_a outputs the miss signal (block 705a).

FIG. 7B illustrates a process for the failure address cache ROW_CACHE_b to output a hit signal or a miss signal upon an input row address signal in accordance with some embodiments. The input row address signal (not shown) may include to an input access index, first input row address and a second input row address.

In block 701b, the input access index is input to the failure address cache ROW_CACHE_b. In block 702b, the failure address cache ROW_CACHE_b may check the validity status corresponding to the input access index. If the validity status corresponding to the input access index is invalid, the failure address cache ROW_CACHE_b outputs the miss signal (block 705b). If the validity status corresponding to the input access index is valid, the failure address cache ROW_CACHE_b proceeds to blocks 703b_1 and 703b_2.

In blocks 703b_1 and 703b_2, the failure address cache ROW_CACHE_b may compare the first and second input row addresses with the first and second failed row addresses corresponding to the input access index. More specifically, in block 703b_1, the failure address cache ROW_CACHE_b may compare the first input row address with the first failed row address stored in the failure address cache ROW_CACHE_b and output a signal A indicating the result of the comparison. When the first input row address matches the first failed row address, the signal A indicates “Same”; and when the first input row address does not match the first failed row address, the signal A indicates “Not same”.

In block 703b_2, the failure address cache ROW_CACHE_b may a compare the second input row address with the second failed row address stored in the failure address cache ROW_CACHE_b and output a signal B indicating the result of the comparison. When the second input row address matches the second failed row address, the signal B indicates “Same”; and when the second input row address does not match the second failed row address, the signal B indicates “Not same”.

In block 703b_3, the failure address cache ROW_CACHE_b may determine whether the first input row address and the second row address matches the first failed row address and the second failed row address according to predetermined logics. The predetermined logics may correspond to a OR logic operation in some embodiments (i.e., the predetermined logics illustrated in below Table 1). As shown in FIG. 1, the failure address cache ROW_CACHE_b outputs the miss signal when both of the signals A and B output “not same” result. Otherwise, the failure address cache ROW_CACHE_b outputs the hit signal.

TABLE 1
Predetermined logics to determine a hit
or a miss of failure address cache

| A | B | Result |
|---|---|---|
| Same | Same | Hit |
| Same | Not same | Hit |
| Not same | Same | Hit |
| Not same | Not same | Miss |

The failure address cache ROW_CACHE_a in FIG. 6A and the ROW_CACHE_b in FIG. 6B may allow or block accesses to the memory according to the hit signal or the miss signal and the memory die that stores the failure address cache ROW_CACHE. For example, failure address caches ROW_CACHE_a and ROW_CACHE_b in the spare die may allow the access to the memory upon the hit signal, and block the access to the memory upon the miss signal. The failure address caches ROW_CACHE_a and ROW_CACHE_b in the normal die may block the access to the memory upon the hit signal, and allow the access to the memory upon the miss signal. The process of controlling the access the memory upon the hit or miss signal of the failure address caches ROW_CACHE_a and ROW_CACHE_b may be same as the processes shown in FIG. 4B and FIG. 4C in some embodiments.

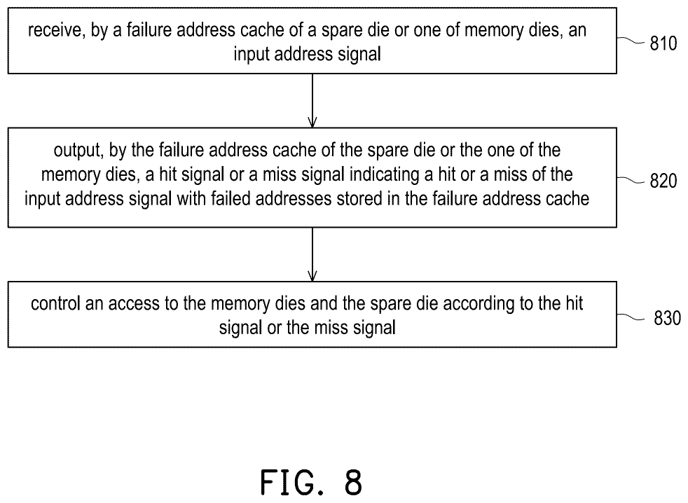

FIG. 8 illustrates a flowchart diagram of method for operating a memory device in accordance with some embodiments. The memory device may include a plurality of memory dies and a spare die stacked to each other, each of the spare die and the memory dies comprises a failure address cache that records failure address information of the memory device. In block 810, the failure address cache of the spare die or one of the memory dies receives an input address signal. In block 820, the failure address cache of the spare die or the one of the memory dies outputs a hit signal or a miss signal, wherein the hit signal or the miss signal indicates a hit or a miss of the input address signal with failed addresses stored in the failure address cache. In block 830, an access to the memory dies and the spare die are controlled according to the hit signal or the miss signal.

In the above embodiments, a spare die is included in a memory device for repairing failed bank groups, failed banks, failed rows in a memory die of the memory device. The spare die may be selected after the memory device is packaged. In this way, the yield of fabricating the memory device is improved. Furthermore, each of the spare die and the memory dies of the memory device may include a failure address cache that records information of failed bank groups, failed banks, failed rows of the memory device. When the failure address cache in the spare die hits, the failure address cache allows access to the memory by transmitting an input address signal and a command associated with the input address signal to the memory. When the failure address cache in the spare die misses, the failure address cache blocks the access to the memory by blocking a transmission of the input address signal and the command associated with the input address signal to the memory. When the failure address cache in the normal die hits, the failure address cache blocks the access to the memory by blocking a transmission of the input address signal and the command associated with the input address signal to the memory. When the failure address cache in the normal die misses, the failure address cache allows the access to the memory by transmitting the input address signal and the command associated with the input address signal to the memory. In this way, the failed bank groups, failed banks and/or failed rows of the memory device can be repair efficiently.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
a plurality of memory dies; and
a spare die, stacked to the memory dies, configured to repair a target memory die among the plurality of memory dies,
wherein each of the spare die and the memory dies comprises a failure address cache that records failure address information of the memory device,
the failure address cache is configured receive an input address signal and output a hit signal or a miss signal, indicating a hit or a miss of the input address signal with failed addresses stored in the failure address cache, and
the memory device is configured to control an access to the memory dies and the spare die according to the hit signal or the miss signal.

2. The memory device of claim 1, wherein
the spare die is determined among a plurality of stacked dies by programing a fuse after the memory device is packaged.

3. The memory device of claim 1, wherein
in response to determining that the failure address cache of the spare die outputs the hit signal, the input address signal and a command associated with the input address signal are transmitted to the spare die of the memory device, and
in response to determining that the failure address cache of the spare die outputs the miss signal, the input address signal and the command associated with the input address signal are blocked from transmitting to the spare die of the memory device.

4. The memory device of claim 1, wherein
in response to determining that the failure address cache of one of the memory dies outputs the hit signal, the input address signal and a command associated with the input address signal are blocked from transmitting to the one of the memory dies of the memory device, and
in response to determining that the failure address cache of one of the memory dies outputs the miss signal, the input address signal and the command associated with the input address signal are transmitted to the one of the memory dies of the memory device.

5. The memory device of claim 1, wherein the failure address cache in each of the spare die and the memory dies comprises:
a bank group field, recording information of a failed bank group of the memory dies in each row of the failure address cache;
a validity field, recording a validity status of each row of the failure address cache;
a rank identification field, recording a rank identification of a failed memory rank that includes the failed bank group;
a failed bank group address field, recording a failed bank group address of the failed bank group in each row of the failure address cache; and
a replaced bank group address field, recording a replaced bank group address of a replaced bank group that replaces the failed bank group in each row of the failure address cache.

6. The memory device of claim 5, wherein
the input address signal is an input bank group address signal;
the failure address cache in each of the spare die and the memory dies is configured to:
receive the input bank group address signal;
output the hit signal in response to determining that the input bank group address signal matches a failed bank group address in the failure address cache, the validity status of the failed bank group is valid, and a rank identification of the input bank group address signal matches the rank identification of the failed memory rank; and
output a miss signal in response to determining that the input bank group address signal does not match the failed bank group address in the failure address cache, the validity status of the failed bank group is invalid, or the rank identification of the input bank group address signal does not match the rank identification of the failed memory rank.

7. The memory device of claim 1, wherein the failure address cache in each of the spare die and the memory dies comprises:
a failed bank address field, recording a failed bank address of a failed bank in each row of the failure address cache;
a replaced bank address field, recording an replaced bank address of a replaced bank that replaces the failed bank in each row of the failure address cache;
a validity field, recording a validity status of each row of the failure address cache; and
a rank identification field, recording a rank identification of a failed memory rank that includes the failed bank.

8. The memory device of claim 7, wherein
the input address signal is an input bank address signal;
the failure address cache in each of the spare die and the memory dies is configured to:
receive the input bank address signal;
output the hit signal in response to determining that the input bank address signal matches a failed bank address in the failure address cache, the validity status of the failed bank group is valid, and a rank identification of the input bank address signal matches the rank identification of the failed memory rank; and
output a miss signal in response to determining that the input bank address signal does not match the failed bank address in the failure address cache, the validity status of the failed bank group is invalid, or the rank identification of the input bank address signal does not match the rank identification of the failed memory rank.

9. The memory device of claim 1, wherein
the failure address cache in each of the spare die and the memory dies comprises a failed cache title field and a failed row address field,
the failed cache title field comprises:
a first validity field, recording a validity status of the cache title;
a rank identification field, recording a rank identification of a failed memory rank that includes a failed row address;
a bank group field, recording a failed bank group that includes the failed row address, and
a failed row address field comprises:
a second validity field, recording a validity status of the failed row address; and
at least one multi-bit modular, recording the failed row address.

10. The memory device of claim 9, wherein
the input address signal is a row address signal, and
the failure address cache in each of the spare die and the memory dies is configured to:
receive the input row address signal;
output the hit signal in response to determining that a cache title associated with the input row address signal matches the failed cache title in the failure address cache, the validity of the failed cache in the failure address cache title is valid, and the row address signal matches the at least one multi-bit modular in the failure address cache; and
output the miss signal in response to determining that the cache title associated with the input row address signal does not match the failed cache title in the failure address cache, the validity of the failed cache in the failure address cache title is invalid, or the row address signal does not match the at least one multi-bit modular in the failure address cache.

11. The memory device of claim 1, wherein the failure address cache in each of the spare die and the memory dies comprises:
an index field, recording an index value in each row of the failure address cache;
a failed row address field, recording a failed row address of a failed row in each row of the failure address cache; and
a validity field, recording a validity status of each row of the failure address cache.

12. The memory device of claim 11, wherein
the input address signal is a row address signal, and
the failure address cache in each of the spare die and the memory dies is configured to:
receive the input row address signal;
output the hit signal in response to determining that the validity status of the failed row address is valid and the input row address signal matches a failed row address in the failure address cache, and
output the miss signal in response to determining that the validity status of the failed row address is invalid or the input row address signal does not match the failed row address in the failure address cache.

13. A method of operating a memory device that includes a plurality of memory dies and a spare die stacked to each other, each of the spare die and the memory dies comprises a failure address cache that records failure address information of the memory device, the method comprising:
receiving, by the failure address cache of the spare die or one of the memory dies, an input address signal;
outputting, by the failure address cache of the spare die or the one of the memory dies, a hit signal or a miss signal indicating a hit or a miss of the input address signal with failed addresses stored in the failure address cache; and
controlling an access to the memory dies and the spare die according to the hit signal or the miss signal.

14. The method of claim 13, further comprising:
determining the spare die among a plurality of stacked dies by programing a fuse after the memory device is packaged.

15. The method of claim 13, further comprising:
in response to determining that the failure address cache of the spare die outputs the hit signal, transmitting the input address signal and a command associated with the input address signal to the spare die of the memory device; and
in response to determining that the failure address cache of the spare die outputs the miss signal, blocking a transmission of the input address signal and the command associated with the input address signal to the spare die of the memory device.

16. The method of claim 13, further comprising:
in response to determining that the failure address cache of one of the memory dies outputs the hit signal, blocking a transmission of the input address signal and a command associated with the input address signal block to the one of the memory dies of the memory device, and
in response to determining that the failure address cache of one of the memory dies outputs the miss signal, transmitting the input address signal and the command associated with the input address signal block to the one of the memory dies of the memory device.

17. The method of claim 13, wherein
the input address signal is an input bank group address signal, and
the method further comprising:
receiving the input bank group address signal;
outputting the hit signal in response to determining that the input bank group address signal matches a failed bank group address in the failure address cache, a validity status of the failed bank group is valid, and a rank identification of the input bank group address signal matches a rank identification of the failed memory rank;
outputting a miss signal in response to determining that the input bank group address signal does not match the failed bank group address in the failure address cache, the validity status of the failed bank group is invalid, or the rank identification of the input bank group address signal does not match the rank identification of the failed memory rank.

18. The method of claim 13, wherein
the input address signal is an input bank address signal, and
the method further comprising:
receiving the input bank address signal;
outputting the hit signal in response to determining that the input bank address signal matches a failed bank address in the failure address cache, a validity status of the failed bank group is valid, and a rank identification of the input bank address signal matches a rank identification of the failed memory rank; and
outputting a miss signal in response to determining that the input bank address signal does not match the failed bank address in the failure address cache, the validity status of the failed bank group is invalid, or the rank identification of the input bank address signal does not match the rank identification of the failed memory rank.

19. The method of claim 13, wherein
the input address signal is a row address, and
the method further comprising:
receiving the input row address signal;
outputting the hit signal in response to determining that a cache title associated with the input row address signal matches the failed cache title in the failure address cache, the validity of the failed cache in the failure address cache title is valid, and the row address matches the at least one multi-bit modular in the failure address cache; and
outputting the miss signal in response to determining that the cache title associated with the input row address signal does not match the failed cache title in the failure address cache, the validity of the failed cache in the failure address cache title is invalid, or the row address does not match the at least one multi-bit modular in the failure address cache.

20. The method of claim 13, wherein
the input address signal is a row address, and
the method further comprising:
receiving the input row address signal;
outputting the hit signal in response to determining that a validity status of the failed row address is valid and the input row address signal matches a failed row address in the failure address cache, and
outputting the miss signal in response to determining that the validity status of the failed row address is invalid or the input row address signal does not match the failed row address in the failure address cache.
